(19) United States
(12) Patent Application Publication
(10) Pub. No.: US 2026/0324382 A1
(43) Pub. Date: Oct. 15, 2026

(54) SEMICONDUCTOR DEVICE AND METHOD OF MANUFACTURING THE SAME

(71) Applicant: RENESAS ELECTRONICS CORPORATION, Tokyo (JP)

(72) Inventors: Naohito SUZUMURA, Tokyo (JP); Tadashi YAMAGUCHI, Tokyo (JP); Tomoki AYANO, Tokyo (JP)

(21) Appl. No.: 19/557,282

(22) Filed: Mar. 5, 2026

(30) Foreign Application Priority Data
Apr. 15, 2025 (JP) 2025-066747

(51) Int. Cl. H10W 20/00; H10W 20/41; H10W 20/42

(52) U.S. Cl. CPC H10W 20/0633; H10W 20/038; H10W 20/0698; H10W 20/422; H10W 20/425; H10W 20/435

(57) ABSTRACT

An anisotropic etching process is performed on a conductive film using a mask film as a mask, using fluorine-containing gas and not using BCl₃ gas, to form a barrier metal film. The barrier metal film has a top surface, a bottom surface, a first side surface, and a second side surface. A portion where the first side surface connects to the bottom surface and a portion where the second side surface connects to the bottom surface are rounded.

### CROSS-REFERENCE TO RELATED APPLICATIONS

The disclosure of Japanese Patent Application No. 2025-066747 filed on Apr. 15, 2025, including the specification, drawings and abstract is incorporated herein by reference in its entirety.

### BACKGROUND

The present disclosure relates to a semiconductor device and a method of manufacturing the same.

There are disclosed techniques listed below.

### Patent Document 1

Japanese Unexamined Patent Application Publication No. 2023-49555

Conventionally, semiconductor devices with wiring using aluminum alloy films have been manufactured. For example, Patent Document 1 discloses a wiring line having a lower barrier metal film, an aluminum alloy film formed on the lower barrier metal film, and an upper barrier metal film formed on the aluminum alloy film.

### SUMMARY

FIGS. 13 and 14 show semiconductor devices of a first examined example, where the present inventors conducted a study on the structure of a wiring line M1. Below, using FIGS. 13 and 14, insights obtained by the inventors from the first examined example are explained.

The wiring line M1 includes a barrier metal film BM1 formed on an interlayer insulating film IL0, a wiring portion AW formed on the barrier metal film BM1, and a barrier metal film BM2 formed on the wiring portion AW.

The first conductive film, the aluminum alloy film, and the second conductive film are sequentially formed on the interlayer insulating film IL0, and an etching process is performed in the order of the second conductive film, the aluminum alloy film, and the first conductive film. As a result, the barrier metal film BM2 is formed from the second conductive film; the wiring portion AW is formed from the aluminum alloy film, and the barrier metal film BM1 is formed from the first conductive film. Subsequently, an interlayer insulating film covering the plurality of wiring lines M1 is formed, and in the interlayer insulating film, a plurality of via plugs V1 reaching the plurality of wiring lines M1 are formed.

The etching process of the aluminum alloy film is carried out as anisotropic plasma etching process. Most of the etching components in the anisotropic etching process include components for etching in the vertical direction, although the anisotropic etching process also includes components for etching in the horizontal direction. Particularly, the aluminum alloy film is etched even upon contact with a specific etching gas (Cl₂). Therefore, based on etching conditions, the horizontal etching components on the aluminum alloy film may increase.

Thus, as shown in FIG. 13, the side surface of wiring portion AW may be recessed relative to the side surface of each of the barrier metal film BM1 and the barrier metal film BM2 under certain etching conditions. In other words, each part of the barrier metal film BM1 and the barrier metal film BM2 may protrude from the side surface of the wiring portion AW. In FIG. 13, a portion of the barrier metal film BM2 protruded from the side surface of the wiring portion AW is shown as eave 11.

In FIG. 13, a portion where the side surface and the top surface of the barrier metal film BM1 connect to each other and a portion where the side surface and the top surface of the barrier metal film BM2 connect to each other are shown as upper corner portions 12. Furthermore, FIG. 13 shows a portion where the side surface and the bottom surface of the barrier metal film BM1 connect to each other and a portion where the side surface and the bottom surface of the barrier metal film BM2 connect to each other as lower corner portions 13.

On the other hand, to reduce the size of semiconductor devices in recent years, the wiring pitch and the distance between the plurality of wiring lines M1 are being narrowed. For example, as shown in FIG. 13, the distance L1 between two wiring lines M1 adjacent to each other is made smaller than the width W of wiring line M1.

Here, misalignment of via plug V1 may occur, and the via plug V1 may be formed between two wiring lines M1 adjacent to each other. In that case, the distance L2 between the barrier metal film BM2 and the via plug V1 and the distance L3 between the barrier metal film BM1 and the via plug V1 become smaller than the distance L1. Thus, compared to when there is no misalignment of via plug V1, two wiring lines M1 adjacent to each other are more likely to be short-circuited via the via plug V1. Additionally, because the electric fields easily concentrate at upper corner portion 12 and lower corner portion 13, short-circuit defects originating from upper corner portion 12 and lower corner portion 13 are likely to occur.

When misalignment of via plug V1 occurs, the via plug V1 is less likely to be formed under eave 11. Thus, although via plug V1 contacts a portion of the top surface and side surface of the barrier metal film BM2, via plug V1 sometimes does not contact the side surface of wiring portion AW. In that case, compared to when there is no misalignment of via plug V1, the contact area between via plug V1 and wiring line M1 becomes smaller. As a result, since the current density increases in portions of the barrier metal film BM2, including eave 11, there is a risk of a reduction in electromigration (EM) lifetime.

Moreover, depending on the conditions of anisotropic plasma etching process on the aluminum alloy film, the side surface of wiring portion AW may become an overhanging side surface 14. In that case, via plug V1 becomes even less likely to contact the side surface 14, further decreasing the EM lifetime.

FIG. 14 shows a state where an interlayer insulating film IL1 covering plurality of wiring lines M1 is formed and via plug V1 is formed in the interlayer insulating film IL1. The interlayer insulating film IL1 is formed, for example, by a deposition process using CVD (Chemical Vapor Deposition) method. However, due to eave 11, the embedding capability of interlayer insulating film IL1 is likely to deteriorate. For instance, since it is difficult to deposit interlayer insulating film IL1 under eave 11, void 15 easily occurs under eave 11 as shown in FIG. 14. If moisture remains in void 15, there is potential for degradation of wiring line M1, therefore the occurrence of void 15 is undesirable.

As described above, in the first examined example, due to the occurrence of short-circuit defects, reduced EM lifetime, and the occurrence of void 15, there is an issue of reduced semiconductor device reliability. Other problems and novel features will become apparent from the description of this specification and the accompanying drawings.

In one embodiment, a manufacturing method of a semiconductor device includes: (a) forming a first conductive film, (b) forming an aluminum alloy film on the first conductive film, (c) forming a second conductive film on the aluminum alloy film, (d) forming a silicon oxide film on the second conductive film, (e) patterning the silicon oxide film to form a mask film, (f) performing an anisotropic etching process on the second conductive film using the mask film as a mask, using fluorine-containing gas and not using BCl₃ gas, to form the second barrier metal film, (g) performing an anisotropic etching process on the aluminum alloy film using the mask film as a mask to form the wiring portion, and (h) performing an anisotropic etching process on the first conductive film using the mask film as a mask to form the first barrier metal film. The second barrier metal film has a first top surface, a first bottom surface, a first side surface, and a second side surface. The wiring portion has a third side surface and a fourth side surface. The maximum width between the first side surface and the second side surface is greater than the maximum width between the third side surface and the fourth side surface. In (f), the portion where the first side surface connects to the first bottom surface and the portion where the second side surface connects to the first bottom surface are rounded.

In one embodiment, a semiconductor device includes a first barrier metal film, a wiring portion formed on the first barrier metal film and formed of aluminum alloy film, and a second barrier metal film formed on the wiring portion. The second barrier metal film has a first top surface, a first bottom surface, a first side surface, and a second side surface. The wiring portion has a third side surface and a fourth side surface. The maximum width between the first side surface and the second side surface is greater than the maximum width between the third side surface and the fourth side surface. The portion where the first side surface connects to the first bottom surface and the portion where the second side surface connects to the first bottom surface are rounded.

According to one embodiment, the reliability of the semiconductor device can be improved.

### BRIEF DESCRIPTION OF THE DRAWINGS

FIG. 1 is a cross-sectional view showing the manufacturing step of a semiconductor device in the first embodiment.

FIG. 2 is a cross-sectional view showing the manufacturing step of semiconductor device following FIG. 1.

FIG. 3 is a cross-sectional view showing the manufacturing step of semiconductor devices following FIG. 2.

FIG. 4 is a cross-sectional view showing the manufacturing step of semiconductor device following FIG. 3.

FIG. 5 is a cross-sectional view showing the manufacturing step of semiconductor devices following FIG. 4.

FIG. 6 is a main portion cross-sectional view showing the etching process performed on aluminum alloy film in second examined example, third examined example, and the first embodiment.

FIG. 7 is a cross-sectional view showing the manufacturing step of semiconductor device following FIG. 5.

FIG. 8 is a cross-sectional view showing the manufacturing step of semiconductor device following FIG. 7.

FIG. 9 is a cross-sectional view showing the manufacturing step of semiconductor device following FIG. 8.

FIG. 10 is a cross-sectional view showing the manufacturing step of semiconductor device following FIG. 9.

FIG. 11 is a cross-sectional view showing the semiconductor device in the first embodiment.

FIG. 12 is a cross-sectional view showing the manufacturing step of semiconductor device in the second embodiment.

FIG. 13 is a cross-sectional view showing the semiconductor device in first examined example.

FIG. 14 is a cross-sectional view showing the semiconductor device in first examined example.

### DETAILED DESCRIPTION

Hereinafter, embodiments are described in detail with reference to the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

Furthermore, the X direction, Y direction, and Z direction explained herein intersect and are perpendicular to each other. In this specification, the Z direction is the vertical direction, depth direction, or thickness direction of a certain structure.

### FIRST EMBODIMENT

### Manufacturing method of semiconductor device

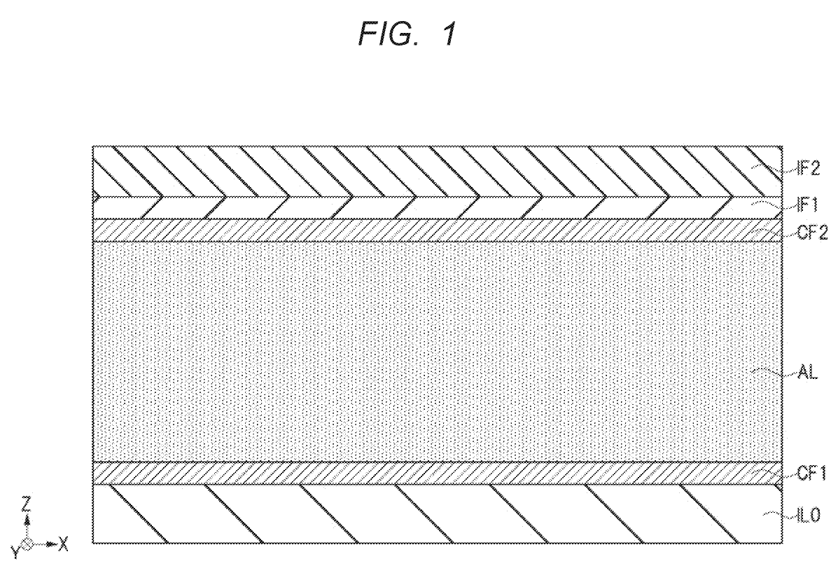

Below, using FIGS. 1 to 11, the manufacturing steps included in the method of manufacturing a semiconductor device in first embodiment are described.

Although not shown, first, a semiconductor substrate is prepared, and a plurality of semiconductor elements such as MOSFET (Metal Oxide Semiconductor Field Effect Transistor) and diodes are formed on the semiconductor substrate. Next, an interlayer insulating film IL0 is formed on the semiconductor substrate. After that, a multilayer wiring layer is formed on the interlayer insulating film IL0. In the first embodiment, the technique of forming the first layer of wiring line M1 of the multilayer wiring layer will be described, but similar techniques can be applied to wiring line above the second layer.

As shown in FIG. 1, first, a conductive film CF1 is formed on the interlayer insulating film IL0. The conductive film CF1 includes titanium film and titanium nitride film. For example, by deposition process using a sputtering method, a titanium film is formed on the interlayer insulating film IL0 and a titanium nitride film is formed on the titanium film. The thickness of the titanium film is, for example, 5 nm or more and 30 nm or less. The thickness of the titanium nitride film is, for example, 5 nm or more and 30 nm or less.

Next, an aluminum alloy film AL is formed on the conductive film CF1, for example, by deposition process using a sputtering method. The aluminum alloy film AL is an aluminum film with added copper or silicon. The thickness of the aluminum alloy film AL is greater than the thickness of the conductive film CF1 and the thickness of the later-described conductive film CF2, for example, 200 nm or more and 500 nm or less.

Next, a conductive film CF2 is formed on the aluminum alloy film AL. The conductive film CF2 includes titanium film and titanium nitride film. For example, by deposition process using a sputtering method, a titanium film is formed on the aluminum alloy film AL and a titanium nitride film is formed on the titanium film. The thickness of the titanium film is, for example, 5 nm or more and 30 nm or less. The thickness of the titanium nitride film is, for example, 5 nm or more and 30 nm or less.

Next, an insulating film IF1 is formed on the conductive film CF2, for example, by deposition process using a CVD method. The insulating film IF1 is, for example, a silicon oxynitride film. The thickness of the insulating film IF1 is, for example, 10 nm or more and 50 nm or less.

Next, an insulating film IF2 is formed on the insulating film IF1, for example, by deposition process using a CVD method. The insulating film IF2 is a oxygen-containing film, for example, a silicon oxide film. The thickness of the insulating film IF2 is, for example, 50 nm or more and 200 nm or less.

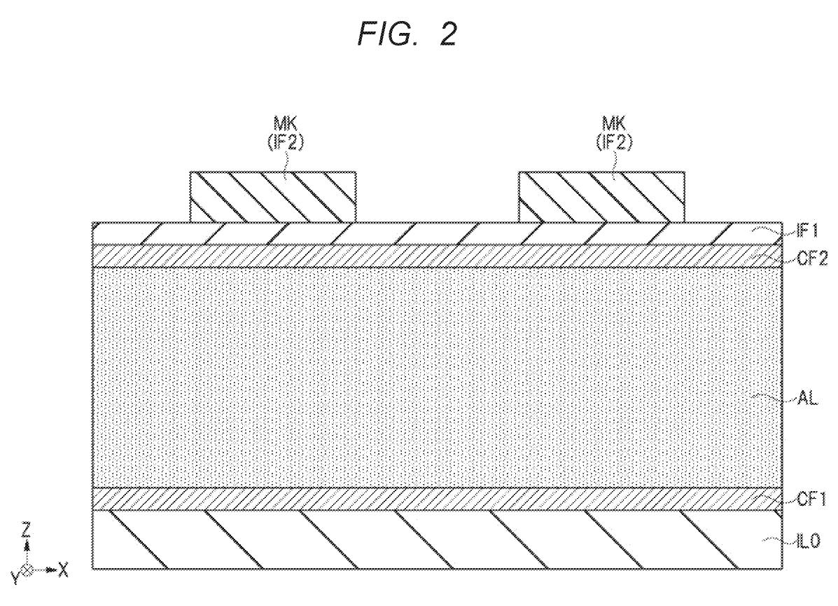

As shown in FIG. 2, a mask film MK is formed by patterning the insulating film IF2 using photolithography technique and anisotropic etching process. At this time, the insulating film IF1 functions as an anti-reflection film.

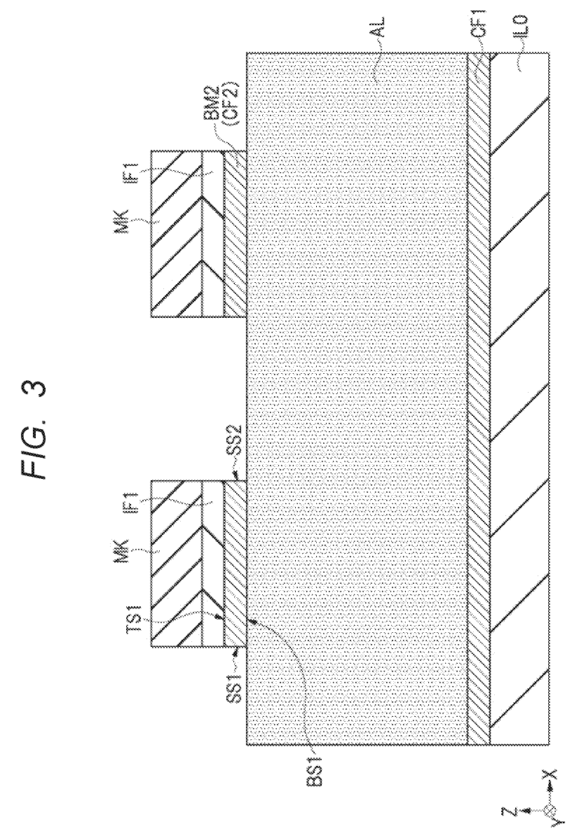

As shown in FIG. 3, first, an anisotropic etching process is performed on the insulating film IF1 using the mask film MK as a mask to remove the insulating film IF1 exposed from the mask film MK. As a result, a portion of insulating film IF1 remains under the mask film MK. This anisotropic etching process uses Cl₂ gas, C₂H₄ gas, and CHF₃ gas.

Next, the conductive film CF2 exposed from the mask film MK is removed by performing an anisotropic etching process on the conductive film CF2 using the mask film MK as a mask to form a barrier metal film BM2. The barrier metal film BM2 remains under the mask film MK and the insulating film IF1. As a result, a portion of the aluminum alloy film AL is exposed from the barrier metal film BM2. This anisotropic etching process uses Cl₂ gas, C₂H₄ gas, and fluorine-containing gas, and does not use BCl₃ gas. The fluorine-containing gas includes, for example, one of CHF₃ gas, CF₄ gas, and CH₂F₂ gas.

The barrier metal film BM2 has a top surface TS1, a bottom surface BS1, a side surface SS1 in the X direction, and a side surface SS2 located opposite to the side surface SS1 in the X direction.

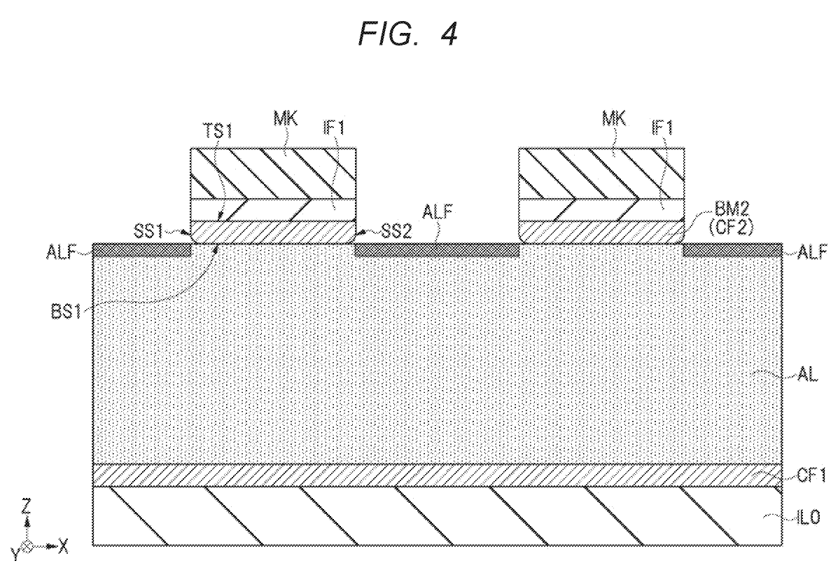

Etching residues of the conductive film CF2 may remain on the aluminum alloy film AL. As shown in FIG. 4, the anisotropic etching process is continued on the conductive film CF2 of FIG. 3 as an over-etching process to completely remove the etching residues of the conductive film CF2. At this time, the portion of the aluminum alloy film AL exposed from the barrier metal film BM2 is exposed to fluorine-containing gas, thereby forming an aluminum fluoride film ALF at the portion of the aluminum alloy film AL exposed from the barrier metal film BM2. The aluminum fluoride film ALF functions as a protective film to protect the aluminum alloy film AL from the over-etching process.

By continuing the over-etching process, a portion of the barrier metal film BM2 is processed. In other words, the portion where the side surface SS1 connects to the bottom surface BS1 and the portion where the side surface SS2 connects to the bottom surface BS1 are rounded. At this time, when BCl₃ gas is used, the degree of rounding becomes less compared to when BCl₃ gas is not used.

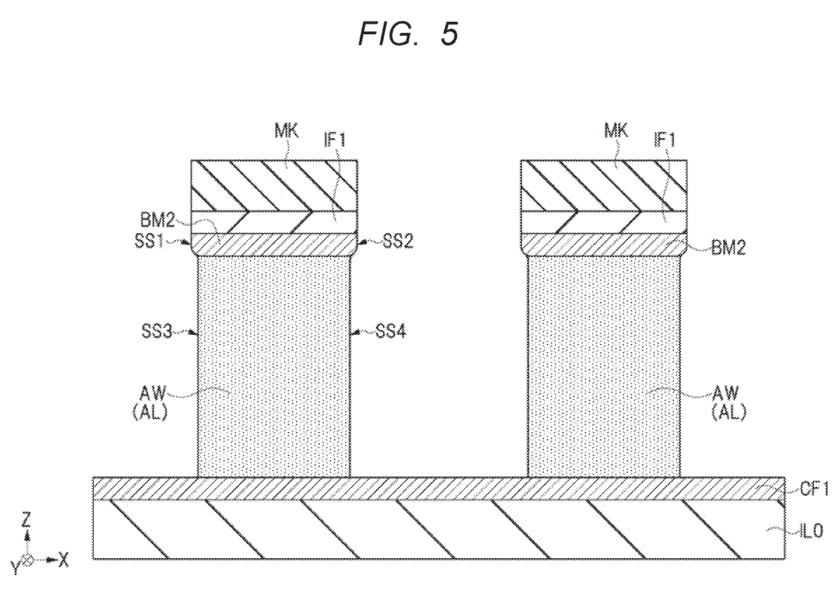

As shown in FIG. 5, the aluminum fluoride film ALF and the aluminum alloy film AL exposed from the mask film MK are removed by performing anisotropic etching process on thr aluminum fluoride film ALF and the aluminum alloy film AL using the mask film MK as a mask to form a wiring portion AW. The wiring portion AW remains under the barrier metal film BM2. This anisotropic etching process uses Cl₂ gas, BCl₃ gas, C₂H₄ gas, and N₂ gas.

The wiring portion AW has a side surface SS3 in the X direction and a side surface SS4 located opposite to the side surface SS3 in the X direction.

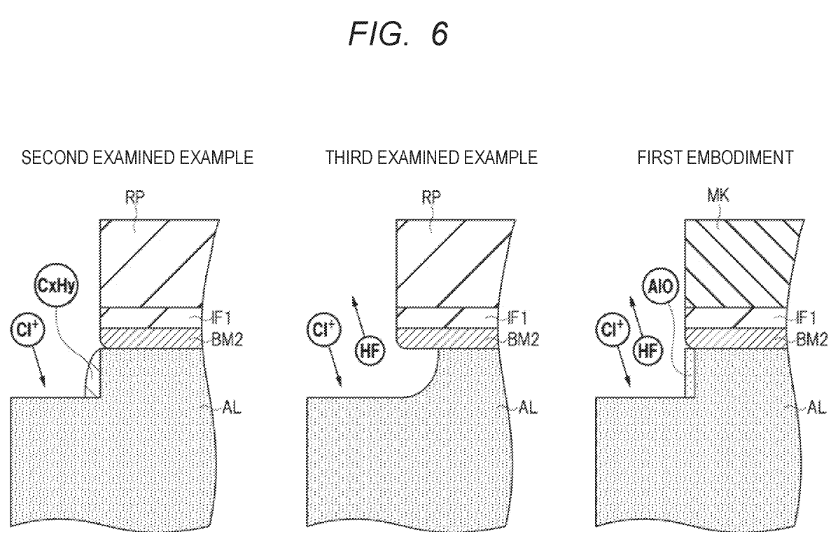

The details of the anisotropic etching process in FIG. 5 will be described with reference to FIG. 6. In the second examined examples and the third examined example shown in FIG. 6, anisotropic etching process is performed using a resist pattern RP as a mask instead of the mask film MK. Also, aluminum fluoride film ALF is not formed in second examined example, but aluminum fluoride film ALF is formed in third examined example.

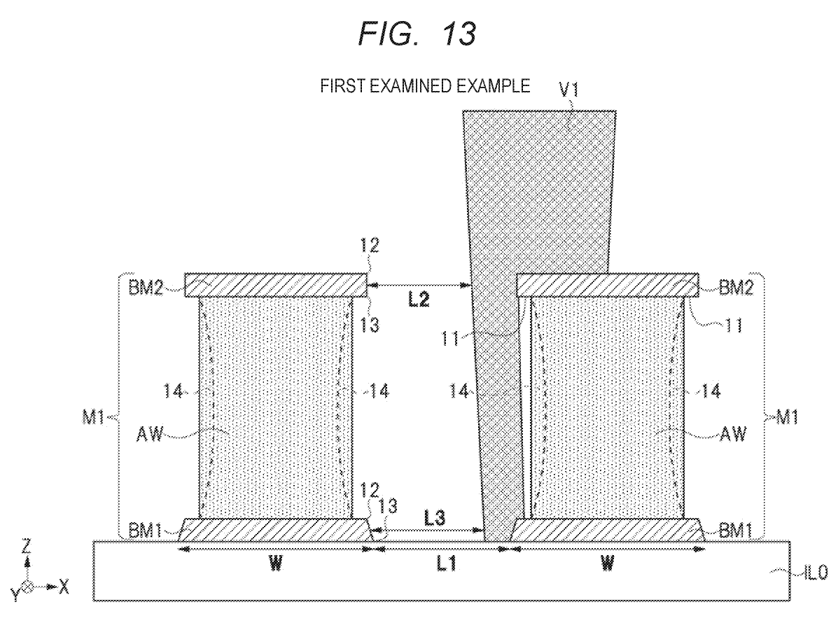

During the anisotropic etching process of second examined example, deposits like CxHy are formed on the processed surface of the aluminum alloy film AL, while the aluminum alloy film AL and deposits are etched with chlorine ions (Cl⁺) as the main etching component. Since the deposits function as a protective film against lateral etching components, eaves 11 like in first examined example of FIG. 13 are not easily formed. It should be noted that "the processed surface of aluminum alloy film AL" described in this specification refers to the portion of the aluminum alloy film AL during anisotropic etching process, which later becomes the side surfaces (side surface SS3, side surface SS4) of the wiring portion AW.

However, in second examined example, since aluminum fluoride film ALF is not formed, if rounding is attempted at the portion where the side surface SS1 connects to the bottom surface BS1, and the portion where the side surface SS2 connects to the bottom surface BS1 during the over-etching process of FIG. 4, aluminum alloy film AL is also etched. As a result, plurality of wiring portions AW are formed on the same semiconductor substrate, but the thickness of the aluminum alloy film AL configuring the plurality of wiring portions AW tends to vary easily.

In third examined example, since aluminum fluoride film ALF is formed, it is possible to suppress the variation in thickness of aluminum alloy film AL. However, during the anisotropic etching process of third examined example, the influence of aluminum fluoride film ALF makes it difficult for deposits like CxHy to form. That is, the aluminum alloy film AL reacts with chlorine ions (Cl⁺) and volatilizes as aluminum chloride (AlCl), while fluorine reacts with hydrogen and volatilizes as hydrogen fluoride (HF). This phenomenon becomes more pronounced as the thickness of the aluminum fluoride film ALF increases. Therefore, due to lateral etching components, the aluminum alloy film AL located under the barrier metal film BM2 is easily etched, making eaves 11 like those in first examined example of FIG. 13 easy to form.

Even in the first embodiment, the influence of aluminum fluoride film ALF makes it difficult for deposits like CxHy to form. However, anisotropic etching process is performed using the mask film MK made of a film containing oxygen as a mask. Therefore, while an aluminum oxide (AlO) film is formed on the processed surface of the aluminum alloy film AL, the wiring portion AW is formed. Since the aluminum oxide (AlO) film functions as a protective film against lateral etching components, eaves 11 like those in first examined example of FIG. 13 are not easily formed.

By suppressing lateral etching components, the recesses of the side surface SS3 and the side surface SS4 of the wiring portion AW is suppressed, and by the manufacturing step shown in FIG. 4, the portion where the side surface SS1 connects to the bottom surface BS1 and the portion where the side surface SS2 connects to the bottom surface BS1 are rounded. By forming wiring portion AW in this manner, as shown in FIG. 5, the portion where the side surface SS1 connects to the bottom surface BS1 is flush with the side surface SS3, and the portion where the side surface SS2 connects to the bottom surface BS1 is flush with the side surface SS4.

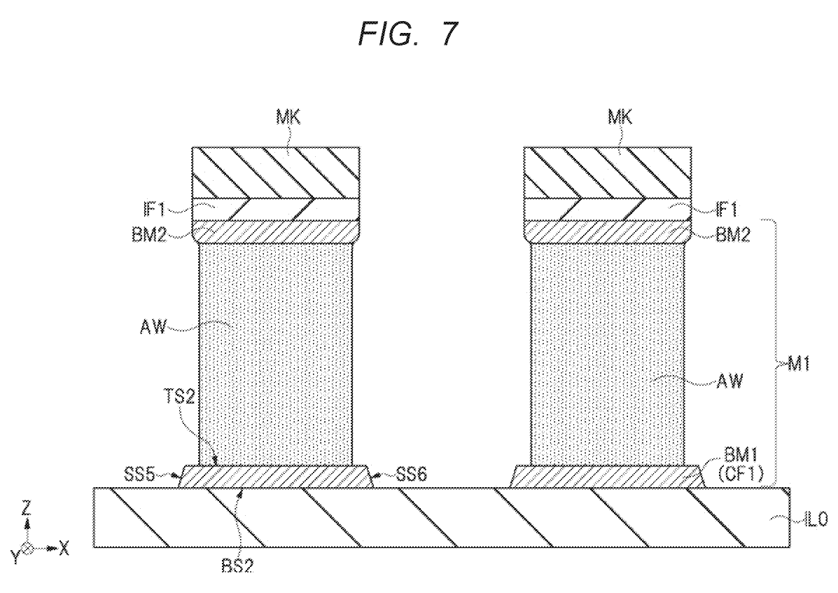

As shown in FIG. 7, the conductive film CF1 is exposed from the mask film MK by performing anisotropic etching process on the conductive film CF1 using the mask film MK as a mask to form a barrier metal film BM1. The barrier metal film BM1 remains under the wiring portion AW. This anisotropic etching process uses Cl₂ gas, BCl₃ gas, C₂H₄ gas, and N₂ gas.

The barrier metal film BM1 has a top surface TS2, a bottom surface BS2, a side surface SS5 in the X direction, and a side surface SS6 located opposite to side surface SS5 in the X direction. Thus, the wiring line M1 having the barrier metal film BM1, the wiring portion AW, and the barrier metal film BM2 is formed.

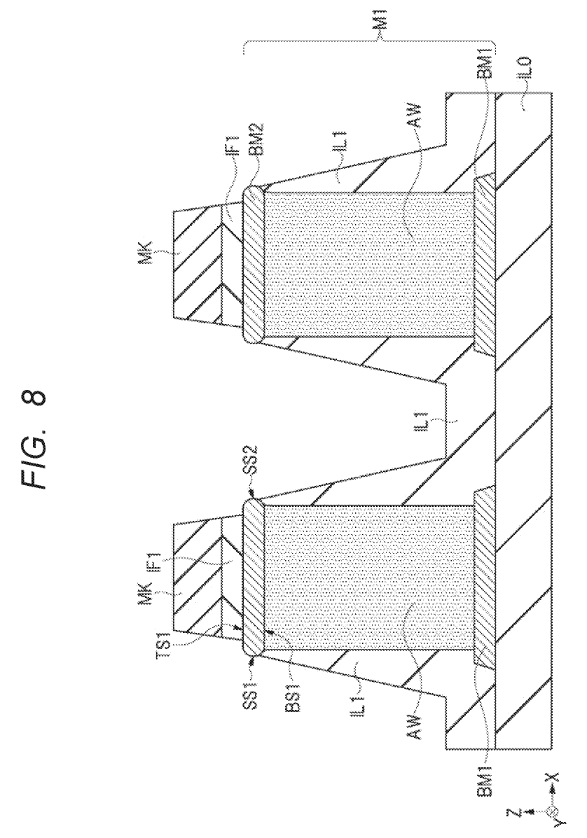

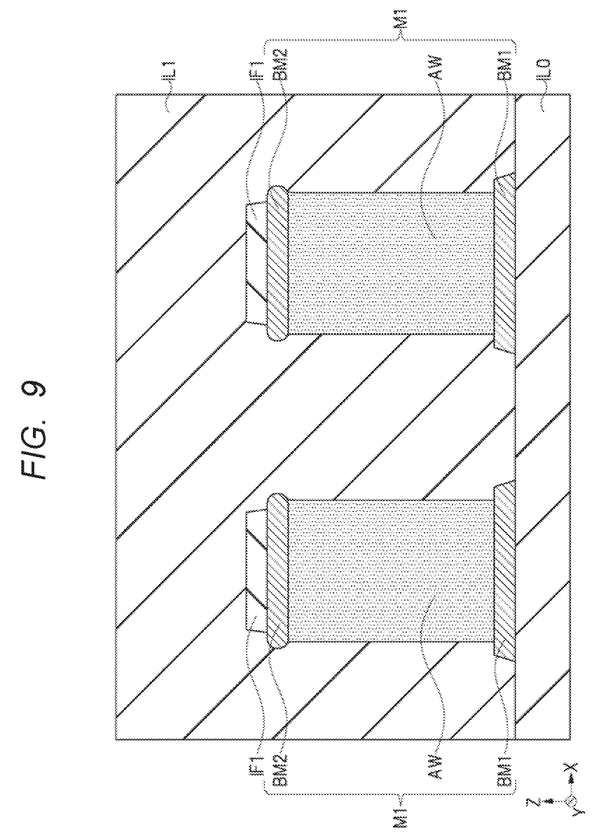

As shown in FIGS. 8 and 9, the interlayer insulating film IL1 covering the barrier metal film BM1, the wiring portion AW, and the barrier metal film BM2 is formed on the interlayer insulating film IL0, by deposition process using HDP-CVD (High Density Plasma-CVD) method. The interlayer insulating film IL1 is, for example, a silicon oxide film.

FIG. 8 shows the state during the formation of the interlayer insulating film IL1. In the deposition process using the HDP-CVD method, deposition and anisotropic etching proceed simultaneously. Therefore, the insulating film IF1 and mask film MK located on the barrier metal film BM2 are exposed to anisotropic etching. Thus, as shown in FIG. 8, a part of the top surface TS1 of the barrier metal film BM2 is exposed. Furthermore, when the deposition process using the HDP-CVD method is continued, the barrier metal film BM2 is also exposed to anisotropic etching, rounding the portion where the side surface SS1 connects to the top surface TS1, as well as the portion where the side surface SS2 connects to the top surface TS1.

Afterward, continuing the deposition process using HDP-CVD method until the interlayer insulating film IL1 covers the barrier metal film BM2, the barrier metal film BM2 is no longer exposed to anisotropic etching. As shown in FIG. 9, upon completion of deposition process using HDP-CVD method, the mask film MK, formed of an oxygen-containing film, is removed. The insulating film IF1 is not completely removed and remains on the barrier metal film BM2.

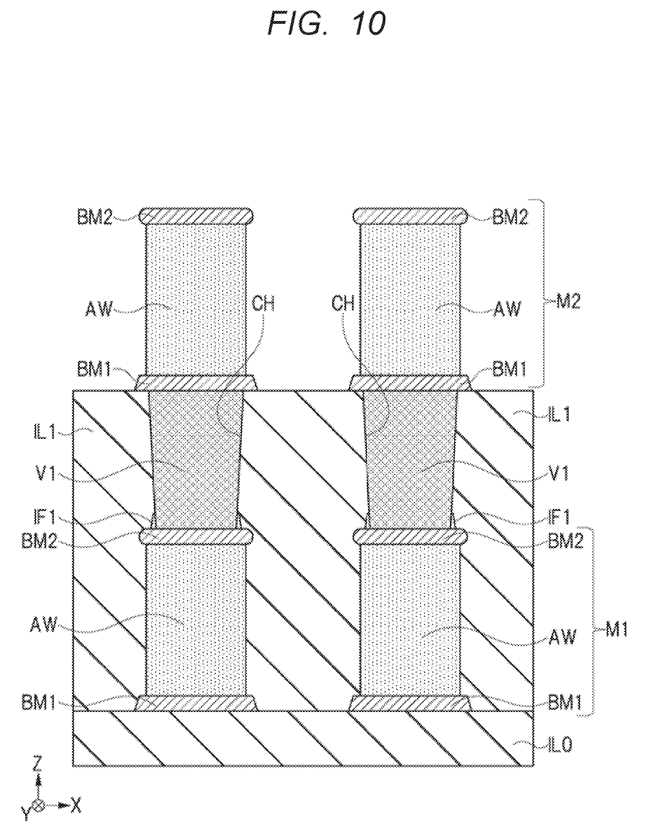

Thereafter, as shown in FIG. 10, the via plug V1 connecting to the wiring line M1 is formed, and the wiring M2 connecting to the via plug V1 is formed.

First, a hole CH that reaches the wiring line M1 is formed in the interlayer insulating film IL1 using photolithography technique and anisotropic etching process. Next, by filling a conductive film in the hole CH, the via plug V1 is formed in the interlayer insulating film IL1. The aforementioned conductive film is formed of a barrier metal film and a metal film formed on the barrier metal film. The barrier metal film is, for example, a titanium nitride film. The metal film is, for example, a tungsten film. Next, using a similar method to the one used for forming the wiring line M1, the wiring line M2 connected to the via plug V1 is formed on the interlayer insulating film IL1. By repetitively forming interlayer insulating films, via plugs, and wiring lines in this manner, a multilayer wiring layer can be formed on the semiconductor substrate.

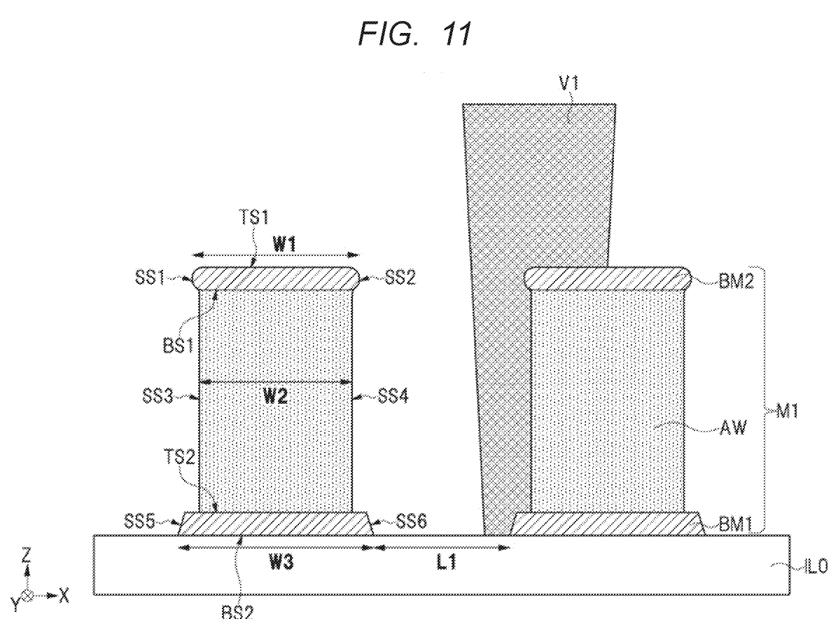

Using FIG. 11, the features of the structure of the wiring line M1 in the first embodiment will be described.

As shown in FIG. 11, in the first embodiment, the side surface SS3 of the wiring portion AW is recessed compared to the side surface SS1 of the barrier metal film BM1 and the side surface SS5 of the barrier metal film BM2, and the side surface SS4 of the wiring portion AW is recessed compared to the side surface SS2 of the barrier metal film BM1 and the side surface SS6 of the barrier metal film BM2. In other words, in the X direction, the maximum width W1 between the side surface SS1 and the side surface SS2, and the maximum width W3 between the side surface SS5 and the side surface SS6, are greater than the maximum width W2 between the side surface SS3 and the side surface SS4.

In the first embodiment, the wiring pitch is narrowed for miniaturization of the semiconductor device. For example, the distance L1 between the barrier metal film BM1 of one of two wiring lines M1 adjacent to each other and the barrier metal film BM1 of the other of two wiring lines M1 is smaller than the maximum width W1 and maximum width W3. Here, if misalignment of the via plug V1 occurs, the two wiring lines M1 adjacent to each other are more likely to be short-circuited. In particular, as in first examined example shown in FIG. 13, it becomes easier for short-circuit defect to occur originating from the upper corner portion 12 and lower corner portion 13 due to the concentration of the electric field.

In the first embodiment, the portions corresponding to the upper corner portion 12 and lower corner portion 13 of the barrier metal film BM2 are rounded. That is, the portion where side surface SS1 connects to bottom surface BS1, and the portion where side surface SS2 connects to bottom surface BS1 are rounded, as well as the portion where side surface SS1 connecs to top surface TS1, and the portion where side surface SS2 connects to top surface TS1 are rounded. Therefore, the concentration of the electric field near the side surface SS1 and the side surface SS2 of the barrier metal film BM2 can be mitigated, thereby preventing the occurrence of short-circuit defects between two wiring lines M1 adjacent to each other.

In addition, in the first embodiment, the formation of an eave 11 as in first examined example shown in FIG. 13 can be suppressed, and the portion where side surface SS1 connects to the bottom surface BS1 is flush with the side surface SS3, as well as the portion where the side surface SS2 connects to the bottom surface BS1 is flush with side surface SS4. Therefore, even if misalignment of the via plug V1 occurs, the via plug V1 contacts a portion of the top surface TS1 of the barrier metal film BM2 and side surface SS1 (side surface SS2) of the barrier metal film BM2, as well as side surface SS3 (side surface SS4) of the wiring portion AW. Compared to first examined example, the contact area between the via plug V1 and wiring line M1 becomes greater. Accordingly, since current density can be dispersed, a decrease in EM lifetime can be suppressed.

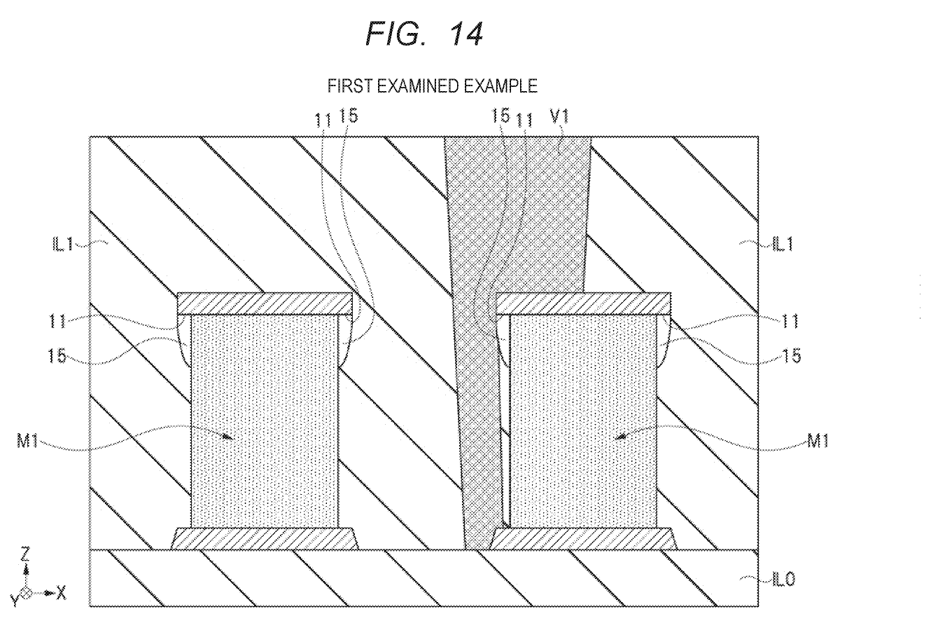

Also, since the formation of eave 11 can be suppressed in the first embodiment, the embedding property of interlayer insulating film IL1 can be improved, and the occurrence of voids 15 as in first examined example shown in FIG. 14 can be suppressed. Thus, defects such as moisture remaining in voids 15 can be suppressed.

As described above, in the first embodiment, the occurrence of short-circuit defects, reduction of EM lifetime, and occurrence of voids 15 can be suppressed, thereby improving the reliability of the semiconductor device.

### SECOND EMBODIMENT

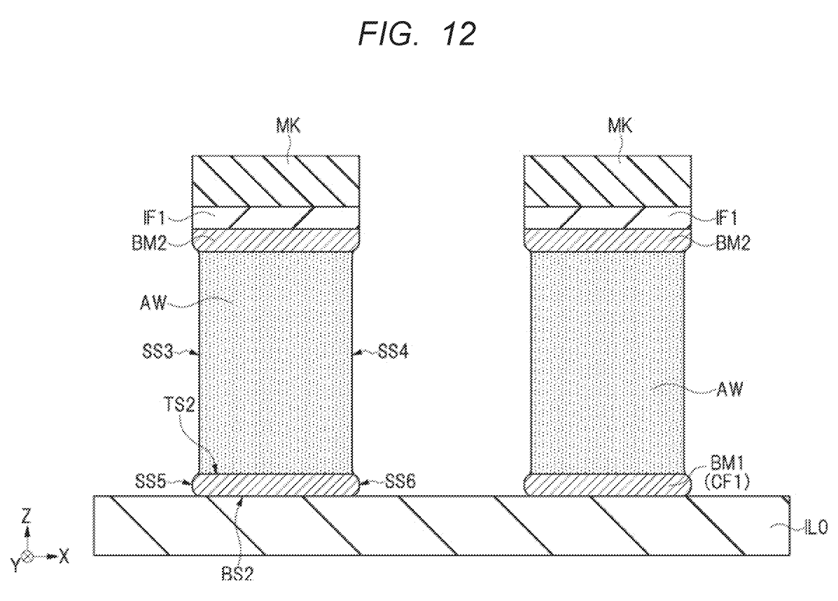

Below, the semiconductor device in the second embodiment will be described using FIG. 12. Note that the description below will focus on the differences from the first embodiment, and points of overlap with the first embodiment will be omitted.

In the second embodiment, not only the upper corner portion 12 and lower corner portion 13 of the barrier metal film BM2 are rounded, but also the upper corner portion 12 and lower corner portion 13 of the barrier metal film BM1 are rounded. To process into such a shape, instead of the manufacturing step shown in FIG. 7, the manufacturing step shown in FIG. 12 is performed.

After performing the manufacturing steps shown from FIGS. 1 to 5, as shown in FIG. 12, anisotropic etching process is performed on the conductive film CF1 using the mask film MK as a mask to form the barrier metal film BM1. The anisotropic etching process in FIG. 12 uses Cl₂ gas, C₂H₄ gas, and fluorine-containing gas, without using BCl₃ gas. The fluorine-containing gas includes, for example, one of CHF₃ gas, CF₄ gas, and CH₂F₂ gas.

Thus, the portion where side surface SS5 connects to bottom surface BSb, and the portion where side surface SS6 connects to bottom surface BS2 are rounded, as well as the portion where side surface SS5 connects to top surface TS2, and the portion where side surface SS6 connects to top surface TS2 are rounded. Furthermore, the portion where side surface SS5 connects to top surface TS2 is flush with side surface SS3, and the portion where side surface SS6 connects to top surface TS2 is flush with side surface SS4. Therefore, the concentration of the electric field near the side surface SS5 and the side surface SS6 of the barrier metal film BM1 can be mitigated, further suppressing the occurrence of short failures between two wiring lines M1 adjacent to each other.

Although the present invention has been specifically described based on the embodiments above, it is not limited to these embodiments, and various modifications can be made without departing from the gist of the invention.

What is claimed is:

1. A method of manufacturing a semiconductor device, the method comprising:
(a) forming a first conductive film;
(b) forming an aluminum alloy film on the first conductive film;
(c) forming a second conductive film on the aluminum alloy film;
(d) forming a silicon oxide film on the second conductive film;
(e) patterning the silicon oxide film to form a mask film;
(f) performing an anisotropic etching process on the second conductive film using the mask film as a mask, using fluorine-containing gas and not using BCl₃ gas, to form a second barrier metal film;
(g) performing an anisotropic etching process on the aluminum alloy film using the mask film as a mask to form a wiring portion; and
(h) performing an anisotropic etching process on the first conductive film using the mask film as a mask to form a first barrier metal film,
wherein the second barrier metal film comprises:
a first top surface;
a first bottom surface;
a first side surface; and
a second side surface located opposite to the first side in a first direction,
wherein the wiring portion comprises:
a third side surface; and
a fourth side surface located opposite to the third side surface in the first direction,
wherein in the first direction, a maximum width between the first side surface and the second side surface is greater than a maximum width between the third side surface and the fourth side surface, and
wherein in the (f), a portion where the first side surface connects to the first bottom surface and a portion where the second side surface connects to the first bottom surface are rounded.

2. The method according to claim 1, comprising:
(i) forming an interlayer insulating film covering the first barrier metal film, the wiring portion, and the second barrier metal film by a film deposition process using HDP-CVD method,
wherein in the (i), a portion where the first side surface connects to the first top surface and a portion where the second side surface connects to the first top surface are rounded.

3. The method according to claim 2,
wherein the portion where the first side surface connects to the first bottom surface is flush with the third side surface, and
wherein the portion where the second side surface connects to the first bottom surface is flush with the fourth side surface.

4. The method according to claim 1,
wherein in the (f), an aluminum fluoride film is formed on a portion of the aluminum alloy film exposed from the second barrier metal film, and
wherein the aluminum fluoride film functions as a protective film to protect the aluminum alloy film from the anisotropic etching process in the (f).

5. The method according to claim 1,
wherein the wiring portion is formed while an aluminum oxide film is formed on a processed surface of the aluminum alloy film during the anisotropic etching process in the (g), and
wherein the processed surface is the third side surface or the fourth side surface.

6. The method according to claim 1,
wherein the fluorine-containing gas used in the (f) is one of CHF₃ gas, CF₄ gas, and CH₂F₂6gas.

7. The method according to claim 1,
wherein the second conductive film comprises a titanium film and a titanium nitride film.

8. The method according to claim 1,
wherein the first barrier metal film comprises:
a fifth side surface; and
a sixth side surface located opposite to the fifth side surface in the first direction,
wherein in the first direction, a maximum width between the fifth side surface and the sixth side surface is greater than the maximum width between the third side surface and the fourth side surface,
wherein the semiconductor device comprises a plurality of wiring lines,
wherein each of the plurality of wiring lines comprises the first barrier metal film, the wiring portion, and the second barrier metal film,
wherein the plurality of wiring lines are spaced apart from each other in the first direction, and
wheren in the first direction, a distance between the second barrier metal film of one of two wiring lines adjacent to each other among the plurality of wiring lines and the second barrier metal film of the other of the two wiring lines is smaller than the maximum width between the fifth side surface and the sixth side surface.

9. The method according to claim 1,
wherein in the (h), the first barrier metal film is formed to perform the anisotropic etching process on the first conductive film using the mask film as a mask, using a fluorine-containing gas and not using BCl₃ gas,
wherein the first barrier metal film comprises:
a second top surface;
a second bottom surface;
a fifth side surface; and
a sixth side surface located opposite to the fifth side surface in the first direction,
wherein in the first direction, a maximum width between the fifth side surface and the sixth side surface is greater than the maximum width between the third side surface and the fourth side surface, and
wherein in the (h), a portion where the fifth side surface connects to the second bottom surface, a portion where the sixth side surface connects to the second bottom surface, a portion where the fifth side surface connects to the second top surface, and a portion where the sixth side surface connects to the second top surface are rounded.

10. The method according to claim 9,
wherein the fluorine-containing gas used in the (h) is one of CHF₃ gas, CF₄ gas, and CH₂F₂10gas.

11. The method according to claim 9,
wherein the first conductive film comprises a titanium film and a titanium nitride film.

12. A semiconductor device comprising:
a first barrier metal film;
a wiring portion formed on the first barrier metal film and formed of an aluminum alloy film; and
a second barrier metal film formed on the wiring portion,
wherein the second barrier metal film comprises:
a first top surface;
a first bottom surface;
a first side surface; and
a second side surface located opposite to the first side surface in the first direction,
wherein the wiring portion comprises:
a third side surface; and
a fourth side surface located opposite to the third side surface in the first direction,
wherein in the first direction, a maximum width between the first side surface and the second side surface is greater than a maximum width between the third side surface and the fourth side surface, and
wherein a portion where the first side surface connects to the first bottom surface and a portion where the second side surface connects to the first bottom surface are rounded.

13. The semiconductor device according to claim 12,
wherein a portion where the first side surface connects to the first top surface and a portion where the second side surface connects to the first top surface are rounded.

14. The semiconductor device according to claim 12,
wherein the portion where the first side surface connects to the first bottom surface is flush with the third side surface, and
wherein the portion where the second side surface connects to the first bottom surface is flush with the fourth side surface.

15. The semiconductor device according to claim 12,
wherein the second barrier metal film comprises a titanium film and a titanium nitride film.

16. The semiconductor device according to claim 12,
wherein the first barrier metal film comprises:
a fifth side surface; and
a sixth side surface located opposite to the fifth side surface in the first direction,
wherein in the first direction, a maximum width between the fifth side surface and the sixth side surface is greater than the maximum width between the third side surface and the fourth side surface,
wherein the semiconductor device comprises a plurality of wiring lines,
wherein each of the plurality of wiring lines comprises the first barrier metal film, the wiring portion, and the second barrier metal film,
wherein the plurality of wiring lines are spaced apart from each other in the first direction, and
wheren in the first direction, a distance between the second barrier metal film of one of two wiring lines adjacent to each other among the plurality of wiring lines and the second barrier metal film of the other of the two wiring lines is smaller than the maximum width between the fifth side surface and the sixth side surface.

17. The semiconductor device according to claim 12,
wherein the first barrier metal film comprises:
a second top surface;
a second bottom surface;
a fifth side surface; and
a sixth side surface located opposite to the fifth side surface in the first direction,
wherein in the first direction, a maximum width between the fifth side surface and the sixth side surface is greater than the maximum width between the third side surface and the fourth side surface,
wherein a portion where the fifth side surface connects to the second bottom surface, a portion where the sixth side surface connects to the second bottom surface, a portion where the fifth side surface connects to the second top surface, and a portion where the sixth side surface connects to the second top surface are rounded.

18. The semiconductor device according to claim 17,
wherein the first barrier metal film comprises a titanium film and a titanium nitride film.
